(19) United States
(12) Patent Application Publication
(10) Pub. No.: US 2010/0123466 A1
(43) Pub. Date: May 20, 2010

(54) System and Method for Corner Frequency Compensation

(76) Inventors: Yongtao Wang, Plano, TX (US); Khurram Muhammad, Dallas, TX (US)

Correspondence Address: TEXAS INSTRUMENTS INCORPORATED, P O BOX 655474, M/S 3999, DALLAS, TX, 75265, US

(21) Appl. No.: 12/272,008

(22) Filed: Nov. 17, 2008

(51) Int. Cl. G01R 27/02

(52) U.S. Cl. 324/605

(57) ABSTRACT

A system and method for corner frequency compensation in a wireless receiver. A method comprises computing a corner frequency of a filter, and determining if the computed corner frequency is different from a desired corner frequency by less than a threshold. The method further comprises if the computed corner frequency differs from the desired corner frequency by more than the threshold, adjusting parameters of the filter to alter the corner frequency, and repeating the computing and the determining. The method additionally comprises if the computed corner frequency differs from the desired corner frequency by less than the threshold, leaving the parameters of the filter unchanged. The computing uses a measured phase response of the filter at a frequency outside of a passband of the filter.

### TECHNICAL FIELD

The present invention relates generally to a system and method for wireless communications, and more particularly to a system and method for corner frequency compensation in a wireless receiver.

### BACKGROUND

Analog baseband filters (ABF) are widely used in wireless receivers to help eliminate or attenuate unwanted out-of-band interferers/blockers, which may negatively impact the overall performance of the wireless receivers. In general, an ABF may pass desired signals that are in a band of interest while blocking or attenuating undesired signals that are outside the band of interest.

An ABF, e.g., a low-pass filter, a band-pass filter, a high-pass filter, and so forth, may be designed so that the band of interest lies within the ABF's pass band, while the ABF's stop band encompasses frequencies outside of the band of interest. For example, if the ABF is a low-pass filter, then the ABF's corner frequency f_{c}) or cut-off frequency may be set so that it is above the band of interest. Thereby, the ABF will pass signals at frequencies lower than the corner frequency while attenuating signals at frequencies higher than the corner frequency.

FIG. 1a is a diagram illustrating a magnitude response 100 of an ABF. Magnitude response 100 displays a signal gain (output signal magnitude/input signal magnitude) of the ABF as a function of frequency. As shown in FIG. 1a, the ABF is a low-pass filter with a corner frequency at f_{c}. The magnitude response of the ABF at zero hertz (DC) is shown in FIG. 1a as G₀ and the magnitude response of the ABF at the corner frequency is shown as G_{C}. By definition, the corner frequency of a filter is a frequency where the magnitude response at the frequency is

$$\frac{1}{\sqrt{2}}$$

of the magnitude response at DC, shown as span 105.

However, during the operation of the wireless receiver, filtering characteristics of the ABF may change. The changes may be due to factors such as variations in operating conditions of the wireless receiver, such as temperature, supply voltage, and so forth. The changes in the operating conditions of the wireless receiver may change the corner frequency of the ABF. Therefore, if the corner frequency is increased, then some out-of-band signals that were previously eliminated (or attenuated) may be allowed to pass, while if the corner frequency is decreased, the some of the desired signals may be eliminated (or attenuated). In either case, the performance of the wireless receiver is degraded.

FIG. 1b is a diagram illustrating a magnitude response 120 of an ABF wherein the corner frequency of the ABF has increased. The changed corner frequency is shown as f_{c} and the original corner frequency is shown as f_{c}. Since the corner frequency of the ABF has increased, the magnitude response of the ABF at the original corner frequency is higher (shown as span 125). Therefore, the magnitude response of the ABF at the original corner frequency is now greater than

$$\frac{1}{\sqrt{2}}$$

times that of the magnitude response at DC.

FIG. 1c is a diagram illustrating a magnitude response 140 of an ABF wherein the corner frequency of the ABF has decreased. The changed corner frequency is shown as f″_{c} and the original corner frequency is shown as f_{c}. Since the corner frequency of the ABF has decreased, the magnitude response of the ABF at the original corner frequency is lower (shown as span 145). Therefore, the magnitude response of the ABF at the original corner frequency is now smaller than

$$\frac{1}{\sqrt{2}}$$

times that of the magnitude response at DC.

A prior art technique used to determine a corner frequency of an ABF involves measuring a magnitude response of the ABF at DC and at a desired corner frequency. As discussed previously, if the desired corner frequency is substantially equal to the actual corner frequency of the ABF, then the magnitude response of the ABF at the desired corner frequency (G_{EC}) is

$$\frac{1}{\sqrt{2}}$$

of the magnitude response at DC. Therefore, if

$$\vert {G}_{EC} - \frac{{G}_{0}}{\sqrt{2}} \vert$$

is smaller than or equal to a pre-determined error margin, then the actual corner frequency is equal (or about equal) to the desired corner frequency. However, if

$${G}_{EC} > \frac{{G}_{0}}{\sqrt{2}} ,$$

then the actual corner frequency is greater than the desired corner frequency. While, if

$${G}_{EC} > \frac{{G}_{0}}{\sqrt{2}} ,$$

then the actual corner frequency is smaller than the desired corner frequency. In either case, the actual corner frequency may be adjusted by tuning resistive (R), capacitive (C), inductive (L), and/or other parameters of the ABF and the measurement repeated until the actual corner frequency of the ABF has been tuned or compensated to the desired corner frequency.

### SUMMARY OF THE INVENTION

These and other problems are generally solved or circumvented, and technical advantages are generally achieved, by embodiments of a system and a method for corner frequency compensation in a wireless receiver.

In accordance with an embodiment, a method for computing a corner frequency of a filter is provided. The method includes injecting a signal into an input of the filter, measuring a phase response of the filter at the frequency, and computing a corner frequency of the filter using the phase response. The signal has value substantially only at a frequency outside of a passband of the filter.

In accordance with another embodiment, a method for adjusting a corner frequency of a filter is provided. The method includes computing the corner frequency of the filter, wherein the computing uses a measured phase response of the filter at a frequency outside of a passband of the filter, determining if the computed corner frequency is different from a desired corner frequency by more or less than a threshold. The method also includes adjusting parameters of the filter to alter the corner frequency, and repeating the computing and the determining if the computed corner frequency differs from the desired corner frequency by more than the threshold. The method further includes leaving the parameters of the filter unchanged if the computed corner frequency differs from the desired corner frequency by less than the threshold.

In accordance with another embodiment, a receiver is provided. The receiver includes a signal path coupled to a signal input and to a baseband unit, the signal path includes a mixer that demodulates a signal provided by the signal input and changes the signal to a baseband signal, a filter coupled to the mixer, an analog to digital converter, and a decimation filter coupled to the analog to digital converter. The filter attenuates undesired signals outside of a frequency band of interest, the analog to digital converter digitizes the filtered baseband signal, and the decimation filter reduces a number of samples produced by the analog to digital converter. The receiver also includes a signal generator coupled to the filter, a demodulator coupled to the decimation filter and to the signal generator, a value estimator coupled to the demodulator, and a processor coupled to the value estimator. The signal generator generates an out-of-band signal having substantially value only at a frequency outside of a passband of the filter, the demodulator demodulates the reduced digital sample stream produced by the decimation filter with the out-of-band signal, the value estimator extracts a direct current (DC) component from the demodulated digital sample stream and selects a value of the DC component. The processor computes a phase response of the filter from the value provided by the value estimator.

An advantage of an embodiment is that out-of-band signals are used in the compensation of the corner frequency. Since the out-of-band signals will be subsequently eliminated in the wireless receiver, the out-of-band signals do not negatively impact the performance of the wireless receiver by introducing any distortion to desired in-band signals.

A further advantage of an embodiment is that the phase response is used in the compensation of the corner frequency. The use of phase response may make the compensation less sensitive to noise, numerical error, and so forth, which may be present in the process of estimating the corner frequency. Therefore, the compensation of the corner frequency may be performed with greater accuracy.

The foregoing has outlined rather broadly the features and technical advantages of the present invention in order that the detailed description of the embodiments that follow may be better understood. Additional features and advantages of the embodiments will be described hereinafter which form the subject of the claims of the invention. It should be appreciated by those skilled in the art that the conception and specific embodiments disclosed may be readily utilized as a basis for modifying or designing other structures or processes for carrying out the same purposes of the present invention. It should also be realized by those skilled in the art that such equivalent constructions do not depart from the spirit and scope of the invention as set forth in the appended claims.

### BRIEF DESCRIPTION OF THE DRAWINGS

For a more complete understanding of the embodiments, and the advantages thereof, reference is now made to the following descriptions taken in conjunction with the accompanying drawings, in which:

FIG. 1a is a plot illustrating a magnitude response of a filter;

FIG. 1b is a plot illustrating a magnitude response of a filter wherein the corner frequency of the filter has increased;

FIG. 1c is a plot illustrating a magnitude response of a filter wherein the corner frequency of the filter has decreased;

FIG. 2a is a diagram of a high-level view of a portion of a wireless transceiver;

FIG. 2b is a diagram of a portion of a receiver;

FIG. 2c is a diagram of a demodulation unit and a direct current (DC) estimation unit;

FIG. 3a is a flow diagram of a computing of a corner frequency of a filter using out-of-band signals;

FIG. 3b is a flow diagram of a computing of a corner frequency of a filter using out-of-band signals, wherein a receiver containing the filter has components with non-zero phase shifts; and

FIG. 4 is a flow diagram of a sequence of events in the compensating of a corner frequency of a filter.

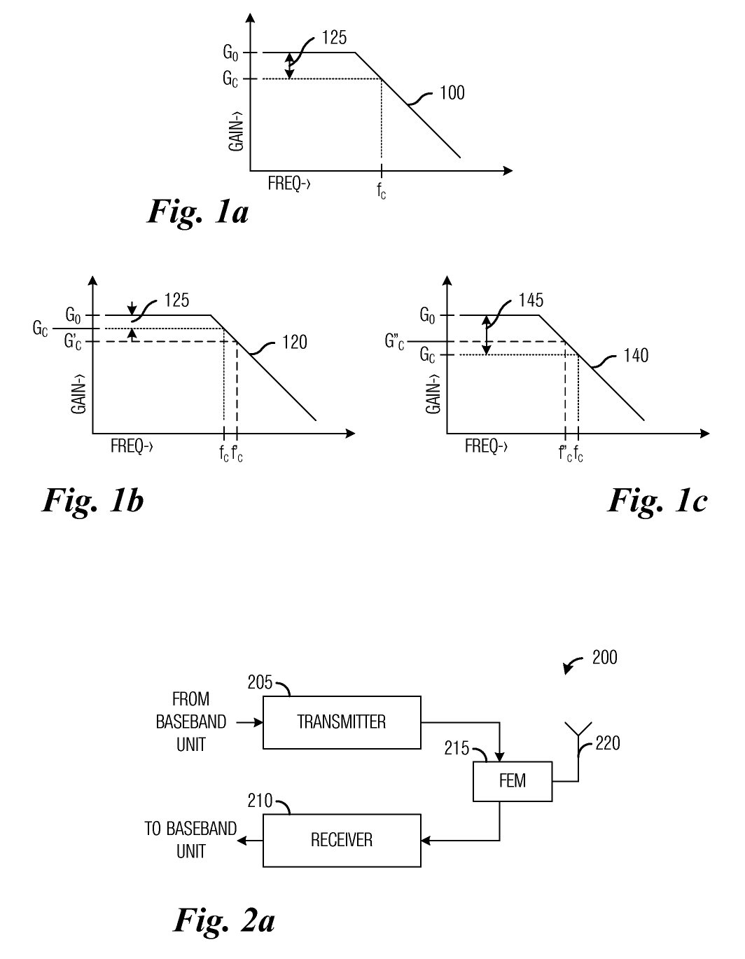

### DETAILED DESCRIPTION OF ILLUSTRATIVE EMBODIMENTS

The making and using of the embodiments are discussed in detail below. It should be appreciated, however, that the present invention provides many applicable inventive concepts that can be embodied in a wide variety of specific contexts. The specific embodiments discussed are merely illustrative of specific ways to make and use the invention, and do not limit the scope of the invention.

The embodiments will be described in a specific context, namely a wireless Cartesian receiver utilizing an analog baseband filter to help reduce or eliminate unwanted out-of-band interferers. The invention may also be applied, however, to other forms of wireless receivers, such as non-Cartesian wireless receivers. Furthermore, the invention may also be applied to other communications devices desiring to use analog filters to help reduce or eliminate interferers that may be present outside of a desired frequency band. The invention is especially important for a full duplex communication system such as the third-generation cellular communication system based on WCDMA. In this kind of system, the receiver continuously receives signals from the air. An advantage of the invention is that out-of-band signals are used in the compensation of the corner frequency. Since the out-of-band signals will be subsequently eliminated in the wireless receiver, the out-of-band signals do not negatively impact the performance of the wireless receiver by introducing any distortion to desired in-band signals.

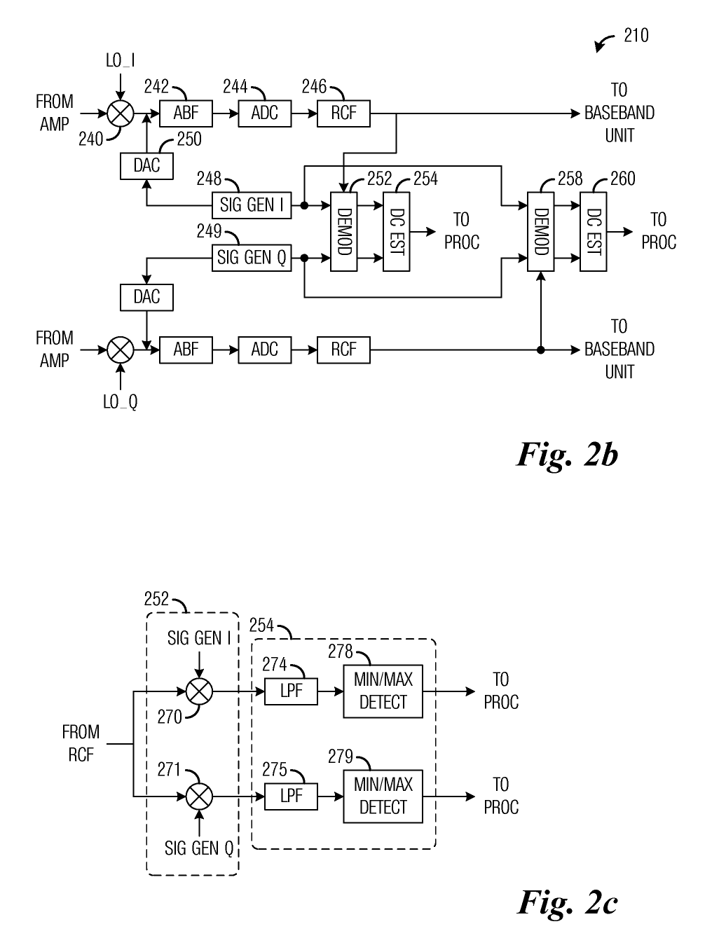

FIG. 2a shows a diagram that illustrates a high-level view of a portion of a wireless transceiver 200. Wireless transceiver 200 includes a transmitter 205, a receiver 210, a front-end module (FEM) 215, and an antenna 220. FEM 215 may include a power amplifier, antenna switches, duplexer, diplexer, SAW filters, and so forth. Transmitter 205 may be used to provide signal processing necessary to transmit information from a baseband unit over the air using antenna 220, while the receiver may be used to provide signal processing to provide information received over the air via antenna 220 to the baseband unit.

Generally, in a transmitter (TX), a digital signal from a digital baseband unit may be processed (for example, filtering, digital-to-analog conversion, etc.) and then modulated onto an RF carrier signal. The RF signal containing the modulated digital signal may then be amplified and radiated through an antenna. This modulation (or up-conversion) in a transmitter may require the use of a local oscillator (LO) or an RF frequency synthesizer (for example, a phase-locked loop). Phase modulation may also be performed at the LO when a polar architecture is adopted for the transmitter. Generally, in a receiver (RX), a received RF signal may be amplified by a low-noise amplifier (LNA) and then down-converted by mixers to an analog baseband signal. There may also be filters between the LNA and the mixers. The analog baseband signal may then be filtered by analog baseband filters and may be further amplified. The baseband signal may then be digitized by an ADC. The down-conversion in the mixers generally requires the use of a local oscillator (LO). The transmitter and the receiver may share a common LO or have separate transmit (TX) LO and receive (RX) LO.

FIG. 2b is a diagram illustrating a portion of receiver 210. The portion of receiver 210 shown in FIG. 2b may be used to determine a corner frequency of an ABF used in receiver 210, as well as to provide compensation for the corner frequency of the ABF if it is determined that the corner frequency has changed. Collectively, when receiver 210 determines the corner frequency and provides compensation of the corner frequency may be referred to as corner frequency compensation. Receiver 210 may periodically perform corner frequency compensation. Alternatively, receiver 210 may perform corner frequency compensation when a specified event occurs. Examples of events may include prior to receiving a transmission, when performance of wireless transceiver 200 reaches a threshold, when measured performance metrics reach a threshold, when a request to perform corner frequency compensation is received, and so forth.

As shown in FIG. 2b, receiver 210 is a Cartesian receiver and has two signal paths, a first signal path for an I-phase and a second signal path for a Q-phase. The discussion of receiver 210 will focus on the first signal path (I-phase). However, the two signal paths are substantially identical and the discussion of the first signal path will also apply to the second signal path.

A received signal, such as one received by antenna 220 and processed by FEM 215, may be provided to receiver 210. Once at receiver 210, the received signal may be amplified by amplifiers, such as a low-noise amplifier and/or a transconductance amplifier. After amplification, the amplified received signal may be provided to the both the first signal path and the second signal path.

In the first signal path, the amplified received signal may be down-converted to an analog baseband signal by mixer 240. Mixer 240 may multiply the amplified received signal with an I-phase output of a local oscillator (LO). In the second signal path, the amplified received signal may similarly be down-converted by another mixer that multiplies it with a Q-phase output of the LO. After conversion to the analog baseband signal by mixer 240, an ABF 242 may be used to filter the analog baseband signal to eliminate or attenuate out-of-band signals. ABF 242 may be a first-order, a second-order, a third-order, or higher low-pass filter, a high-pass filter, a band-pass filter, and so on. The order and type of ABF 242 may be dependent on factors such as the nature of the in-band signal, the nature of the out-of-band signals, the closeness of the out-of-band signals to the in-band signal, and so forth. An ADC 244 may then digitize the output of ABF 242. A decimation filter (RCF) 246 may then be used to reduce the number of digitized samples of the output of ADC 244. The digitized and decimated baseband signal may then be provided to a baseband unit for further processing.

Receiver 210 also includes a first signal generator (SIG GEN I) 248 that may be used to generate an out-of-band signal for use in performing corner frequency compensation. In general, a single signal generator may be used to generate the various out-of-band signals to be used in corner frequency compensation. However, logically, a different signal generator may be used to generate each of the various out-of-band signals. Therefore, since the out-of-band signal used in the first signal path may be different than an out-of-band signal used in the second signal path, a second signal generator (SIG GEN Q) 249 may be used to generate the out-of-band signal for the second signal path.

The out-of-band signal generated by SIG GEN I 248 may be a cosine wave at a desired frequency and the out-of-band signal generated by SIG GEN Q 249 may be a sine wave at the same desired frequency. SIG GEN I 248 (and SIG GEN Q 249) may be implemented as a memory containing a look-up table containing entries descriptive of the out-of-band signal to be generated, for example. Alternatively, an oscillator along with a delay may be used to generate the out-of-band signals needed for the first signal path and the second signal path. Although the discussion focuses on sine and cosine out-of-band signals, other signal forms may be used as the out-of-band signals. Therefore, the discussion of sine and cosine out-of-band signals should not be construed as being limiting to either the scope or the spirit of the embodiments.

The out-of-band signal generated by SIG GEN I 248 may be converted into an analog signal by a DAC 250 and then combined (added, for example) with the analog baseband signal produced by mixer 240. The out-of-band signal in combination with the analog baseband signal may then be filtered by ABF 242, digitized by ADC 244, and decimated by RCF 246. In addition to being provided to the baseband unit, the output of RCF 246 may also be provided to a demodulation unit 252, which may demodulate the output of RCF 246 with the out-of-band signals, as generated by SIG GEN I 248 and SIG GEN Q 249. Additionally, a DC estimation unit 254 may be used to detect a maximum and a minimum value of the output of demodulation unit 252. Collectively, demodulation unit 252 and DC estimation unit 254 may be used to measure a phase response of ABF 242. The maximum and the minimum values of the output of demodulation unit 252 may be provided to a processor, such as a script processor, that may make use of the maximum and the minimum values to compute the corner frequency of ABF 242 and make any adjustments to ABF 242 as needed.

Like demodulation unit 252 and DC estimation unit 254, a demodulation unit 258 and a DC estimation unit 260 may be used to measure a phase response of an ABF in the second signal path. Maximum and minimum values of the output of demodulation unit 258 may also be provided to the processor, where the corner frequency of the ABF in the second signal path may be computed and any adjustments to the ABF may be performed if needed.

Although shown in FIG. 2b as having a separate demodulation unit and DC estimation unit for each signal path, it may be possible to utilize a single demodulation unit and DC estimation unit for both signal paths. The two signal paths may share the demodulation unit and the DC estimation unit. This may lead to a reduction in hardware requirements, thereby potentially reducing complexity and cost.

FIG. 2c is a diagram illustrating a detailed view of demodulation unit 252 and DC estimation unit 254. Although FIG. 2c illustrates a detailed view of demodulation unit 252 and DC estimation unit 254, demodulation unit 258 and DC estimation unit 260 may be substantially similar. Therefore, the discussion of demodulation unit 252 and DC estimation unit 254 also applies to demodulation unit 258 and DC estimation unit 260.

Demodulation unit 252 comprises a first multiplier 270 and a second multiplier 271. First multiplier 270 may be used to demodulate the output of RCF 246 with the out-of-band signal produced by SIG GEN I 248, while second multiplier 271 may be used to demodulate the output of RCF 246 with the out-of-band signal produced by SIG GEN Q 249.

DC estimation unit 254 includes a first filter 274 and a second filter 275, preferably low-pass filters, to remove unwanted high-frequency components from outputs of first multiplier 270 and second multiplier 271, respectively. First filter 274 and second filter 275 may be used to produce DC signals from outputs of first multiplier 270 and second multiplier 271. Filter characteristics of first filter 274 and second filter 275 may be similar and should be set so that as much of non-DC signals present in the outputs of first multiplier 270 and second multiplier 271 as possible are eliminated (or attenuated).

After filtering, a first min/max detector 278 and a second min/max filter 279 may be used to select values (minimum and maximum output values) from the outputs of first filter 274 and second filter 275. First min/max detector 278 and second min/max detector 279 may be implemented comparators and memories, with the comparators used to compare a current output of a filter (either first filter 274 or second filter 275) with minimum and maximum values stored in the memories. Outputs from first min/max detector 278 and second detector 279 may be provided to a processor that may be used to compute the corner frequency of ABF 242 and make necessary adjustments if needed.

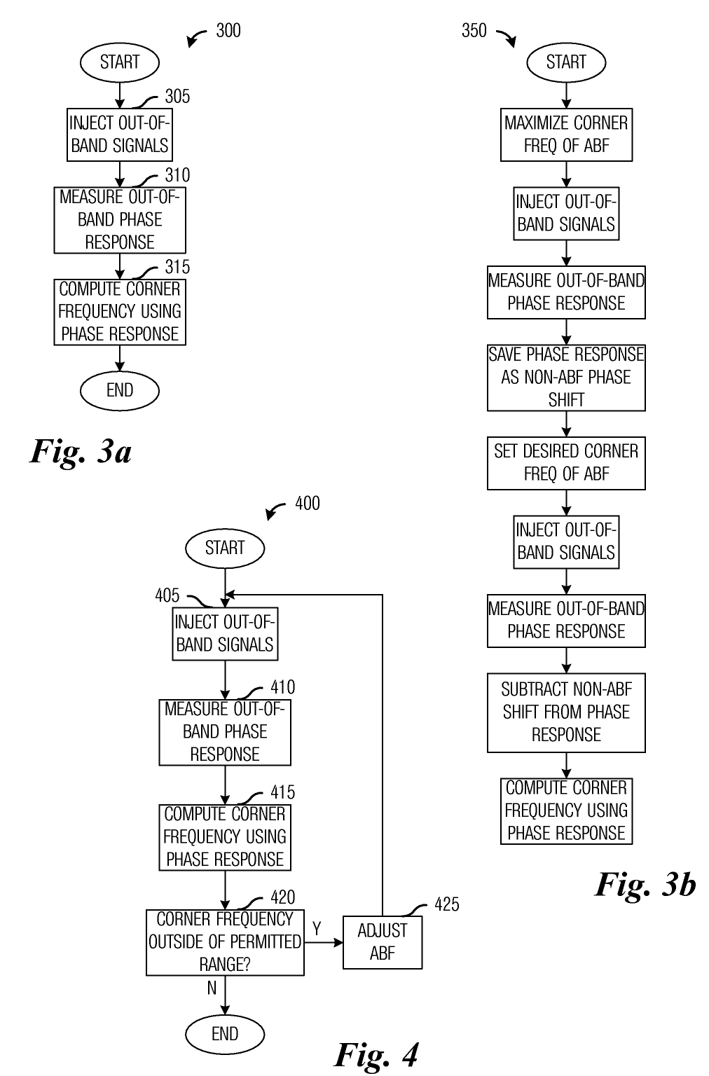

FIG. 3a is a flow diagram illustrating a flow chart 300 in the computing of a corner frequency of a filter using out-of-band signals. Flow chart 300 may be descriptive of operations taking place in a wireless receiver performing corner frequency compensation. The computing of the corner frequency of a filter, such as an ABF, may be performed periodically. Alternatively, the computing of the corner frequency may occur when a specified event occurs. For example, the computing of the corner frequency may occur prior to receiving a transmission, when performance of the wireless transceiver reaches a threshold, when measured performance metrics reach a threshold, when a request to perform corner frequency compensation is received, a detected change in operating conditions, a detected change in supply voltage, and so forth.

The computing of the corner frequency may begin with an injection of out-of-band signals (block 305). Referencing FIG. 2b, the out-of-band signals may be injected by SIG GEN I 248 and SIG GEN Q 249. Examples of out-of-band signals may include cosine waves, sine waves, and so forth. Without loss of generality, let SIG GEN I 248 inject a cosine wave defined as d₀ cos(2πf_{IF}nT) and SIG GEN Q 249 inject a sine wave defined as d₀ sin(2πf_{IF}nT).

After the out-of-band signals have been injected, a phase response of the ABFs of wireless receiver 200, such as ABF 242 and a corresponding ABF of the second signal path, may be measured (block 310). In order to simplify measurement of the phase response, the following assumptions are made: 1) a phase shift introduced by ABF 242 is φ_{I}; 2) a phase shift introduced by ADC 244 is zero (typically true if f_{IF} is not significantly larger than the corner frequency of ABF 242); 3) a phase shift of RCF 246 is known and is zero (also typically true if f_{IF} is not significantly larger than the corner frequency of ABF 242); 4) a phase shift of DAC 250 is zero. Similar assumptions are also made for the second signal path.

If the phase shift due to ADC 244, RCF 246, and/or DAC 250 is non-zero, then the phase shift may be measured using a technique similar to what is described below for measuring the phase shift for use in computing the corner frequency, but with adjustments made to ABF 242 so that the corner frequency of ABF 242 is at its maximum value. By maximizing the corner frequency of ABF 242, the phase shift introduced by ABF 242 may be negligible. The measured phase shift due to ADC 244, RCF 246, and/or DAC 250 may then be removed (for example, subtracted) from a measured phase shift due to ABF 242 and ADC 244, RCF 246, and/or DAC 250. This may then yield the phase shift due to ABF 242 alone. FIG. 3b is a flow diagram illustrating a flow chart 350 in the computing of a corner frequency of a filter using out-of-band signals, wherein the phase shift due to ADC 244, RCF 246, and/or DAC 250 is non-zero.

Denote the output of RCF 246 as d₁ cos(2πf_{IF}nT+θ_{I}). From θ_{I}, θ_{I} may be computed as being equal to either θ_{I} or θ_{I} minus the phase shift due to DAC 250, RCF 246, and/or ADC 224 (as discussed above).

Referencing FIG. 2c, an output of multiplier 270 is expressible as:

$$\begin{matrix}{M}_{I} = {d}_{1} cos ( 2 π {f}_{IF} nT + θ ) {d}_{0} cos ( 2 π {f}_{IF} nT ) \\ = \frac{1}{2} {d}_{0} {d}_{1} [ cos ( {θ}_{I} ) + cos ( 4 π {f}_{IF} nT + {θ}_{I} )\end{matrix}$$

and an output of multiplier 271 is expressible as:

$$\begin{matrix}{M}_{Q} = {d}_{1} cos ( 2 π {f}_{IF} nT + {θ}_{I} ) {d}_{0} sin ( 2 π {f}_{IF} nT ) \\ = - \frac{1}{2} {d}_{0} {d}_{1} [ sin ( {θ}_{I} ) - sin ( 4 π {f}_{IF} nT + {θ}_{I} ) ] .\end{matrix}$$

After first filter 274 and second filter 275 remove high frequency terms from the above, they become DC signals expressible as:

$${L}_{I} = \frac{1}{2} {d}_{0} {d}_{1} cos ( {θ}_{I} )$$

$${L}_{Q} = - \frac{1}{2} {d}_{0} {d}_{1} sin ( {θ}_{I} ) .$$

L_{I} and L_{Q} may then be provided to first min/max detector 278 and second min/max detector 279 and the phase of the output of RCF 246 may be solved,

$${θ}_{I} = - {tan}^{- 1} ( \frac{{L}_{Q}}{{L}_{I}} ) .$$

As such, the phase response of ABF 242 φ_{I} may be measured at frequency f_{IF}.

Similarly, the measuring of the phase response of the ABF in the second signal path, φ_{Q}, at frequency f_{IF} with the output of SIG GEN Q 249 as d₀ sin(2πf_{IF}nT) may also be performed. Let an output of an RCF in the second signal path be expressible as d₂ sin(2πf_{IF}nT+θ_{Q}). Then, an output of a multiplier in an I signal path, similar to multiplier 270, is expressible as:

$$\begin{matrix}{\tilde{M}}_{I} = {d}_{2} sin ( 2 π {f}_{IF} nT + {θ}_{Q} ) {d}_{0} cos ( 2 π {f}_{IF} nT ) \\ = \frac{1}{2} {d}_{0} {d}_{2} [ sin ( {θ}_{Q} ) + sin ( 4 π {f}_{IF} nT + {θ}_{Q} ) ]\end{matrix}$$

and an output of a multiplier in a Q signal path, similar to multiplier 271, is expressible as:

$$\begin{matrix}{\tilde{M}}_{Q} = {d}_{2} sin ( 2 π {f}_{IF} nT + {θ}_{Q} ) {d}_{0} sin ( 2 π {f}_{IF} nT ) \\ = \frac{1}{2} {d}_{0} {d}_{2} [ cos ( {θ}_{Q} ) + cos ( 4 π {f}_{IF} nT + {θ}_{Q} ) ] .\end{matrix}$$

After filters remove high frequency terms, the remaining DC signals expressible as:

$${\tilde{L}}_{I} = \frac{1}{2} {d}_{0} {d}_{2} sin ( {θ}_{Q} )$$

$${\tilde{L}}_{Q} = \frac{1}{2} {d}_{0} {d}_{2} cos ( {θ}_{Q} ) .$$

\tilde{L}_{I} and \tilde{L}_{Q} may then be measured by min/max detectors and the phase of the output of the RCF in the second signal path, θ_{Q}, may be solved,

$${θ}_{Q} = {tan}^{- 1} ( \frac{{\tilde{L}}_{I}}{{\tilde{L}}_{Q}} ) .$$

As such, the phase response of the ABF in the second signal path, φ_{Q}, may be measured at frequency f_{IF}.

Referencing back to FIG. 3a, after measuring the phase response of ABF 242 and a corresponding ABF in the second signal path (block 310), the corner frequency of ABF 242 and the corresponding ABF in the second signal path may be computed using the measured phase responses (block 315).

The computing of the corner frequency may be dependent on the order of the ABF. For example, if the ABF is a first order low-pass filter with a transfer function expressible as:

$$H ( s ) = \frac{{G}_{0}}{1 + j \frac{f}{{f}_{c}}} ,$$

where f_{c} is the corner frequency of the ABF and G₀ is the magnitude response at DC, then the phase response of the ABF is expressible as:

$$ϕ = - {tan}^{- 1} ( \frac{f}{{f}_{c}} ) .$$

Therefore, if the measured phase response at f_{I} is equal to φ₁, then the corner frequency may be computed as:

$${f}_{c} = \frac{{f}_{1}}{tan ( {ϕ}_{1} )} .$$

The estimated term in the phase response measurement is tan(φ₁), not φ₁). This may imply that in calculating f_{c}, mathematical functions, such as tan and tan⁻¹, do not have to be used. Since the mathematical functions, such as tan and tan⁻¹, tend to be sensitive to noise, numerical errors, and so forth, the estimation of tan(φ₁) and the computing of the corner frequency may be less affected by noise, numerical errors, and so on.

If the ABF is a second-order low-pass filter with a transfer function expressible as:

$$H ( s ) = \frac{{G}_{0}}{{( \frac{s}{{ω}_{n}} )}^{2} + \frac{1}{Q} ( \frac{s}{{ω}_{n}} ) + 1} .$$

Then the phase response of the ABF is expressible as:

$$ϕ = - {tan}^{- 1} ( \frac{\frac{1}{Q} ( \frac{ω}{{ω}_{n}} )}{1 - {( \frac{ω}{{ω}_{n}} )}^{2}} ) ,$$

where ωₙ is the natural frequency.

Assuming that the phase response at two out-of-band frequencies have been measured (φ₁ and φ₂ at f₁ and f₂, respectively), then:

$${ϕ}_{1} = - {tan}^{- 1} ( \frac{\frac{1}{Q} ( \frac{{ω}_{1}}{{ω}_{n}} )}{1 - {( \frac{{ω}_{1}}{{ω}_{n}} )}^{2}} )$$

$${ϕ}_{2} = - {tan}^{- 1} ( \frac{\frac{1}{Q} ( \frac{{ω}_{2}}{{ω}_{n}} )}{1 - {( \frac{{ω}_{2}}{{ω}_{n}} )}^{2}} ) ,$$

where ω₁=2πf₁ and ω₂=2πf₂. From the above two equations, two unknowns Q and ωₙ (filter parameters) need to be solved. Once solved, the corner frequency may then be computed from Q and ωₙ.

To solve for the two unknowns Q and ωₙ, rewrite the equations for φ₁ and φ₂ above as:

$$- tan ( {ϕ}_{1} ) = \frac{\frac{1}{Q} ( \frac{{ω}_{1}}{{ω}_{n}} )}{1 - {( \frac{{ω}_{1}}{{ω}_{n}} )}^{2}} \\ - tan ( {ϕ}_{2} ) = \frac{\frac{1}{Q} ( \frac{{ω}_{2}}{{ω}_{n}} )}{1 - {( \frac{{ω}_{2}}{{ω}_{n}} )}^{2}} . \\ Then , \\ \frac{tan ( {ϕ}_{1} )}{tan ( {ϕ}_{2} )} = \frac{1 - {( \frac{{ω}_{2}}{{ω}_{n}} )}^{2}}{1 - {( \frac{{ω}_{1}}{{ω}_{n}} )}^{2}} \frac{{ω}_{1}}{{ω}_{2}}$$

$$\frac{tan ( {ϕ}_{1} )}{tan ( {ϕ}_{2} )} \frac{{ω}_{2}}{{ω}_{1}} = \frac{{ω}_{n}^{2} - {ω}_{2}^{2}}{{ω}_{n}^{2} - {ω}_{1}^{2}} . \\ Let k = \frac{tan ( {ϕ}_{1} )}{tan ( {ϕ}_{2} )} \frac{{ω}_{2}}{{ω}_{1}} , then$$

$${ω}_{n}^{2} - {ω}_{2}^{2} = k ( {ω}_{n}^{2} - {ω}_{1}^{2} )$$

$${ω}_{n}^{2} = \frac{k {ω}_{1}^{2} - {ω}_{2}^{2}}{k - 1}$$

$${ω}_{n} = \sqrt{\frac{k {ω}_{1}^{2} - {ω}_{2}^{2}}{k - 1}} .$$

It then follows that

$$Q = \frac{1}{tan ( {ϕ}_{1} ) ( \frac{{ω}_{1}^{2}}{{ω}_{n}^{2}} - 1 ) \frac{{ω}_{n}}{{ω}_{1}}} .$$

At the corner frequency of the second-order ABF,

$$\vert j \frac{{ω}_{c}}{{ω}_{n}} \frac{1}{Q} + 1 - \frac{{ω}_{c}^{2}}{{ω}_{n}^{2}} \vert = \sqrt{2} ,$$

where ω_{c}=2πf_{c}. This implies that:

$${( 1 - {( \frac{{ω}_{c}}{{ω}_{n}} )}^{2} )}^{2} + {( \frac{{ω}_{c}}{{ω}_{n}} )}^{2} \frac{1}{{Q}^{2}} = 2.$$

### Let

$$x = {( \frac{{ω}_{c}}{{ω}_{n}} )}^{2} ,$$

then

$${( 1 - x )}^{2} + \frac{x}{{Q}^{2}} = 2$$

$${x}^{2} + ( \frac{1}{{Q}^{2}} - 2 ) x - 1 = 0.$$

The above equation yields a solution

$$x = \frac{( 2 - \frac{1}{{Q}^{2}} ) + \sqrt{{( 2 - \frac{1}{{Q}^{2}} )}^{2} + 4}}{2} .$$

### Therefore,

$${ω}_{c} = \sqrt{x} {ω}_{n} and {f}_{c} = \frac{\sqrt{x} {ω}_{n}}{2 π} .$$

Furthermore, as discussed above, the avoidance of using math functions, such as tan and tan⁻¹, may make the proposed approach less sensitive to the noise and numerical errors in estimating the corner frequency.

In general, for an n-th order ABF, measurements of the phase response of the ABF may be made at n different out-of-band frequencies. The n phase responses may then be used to solve for n different unknowns, which in turn, may be used to compute the corner frequency. In order to help ensure that the assumptions made above remain valid, the n different out-of-band frequencies should be relatively close to the corner frequency, however, they should be far enough apart so that they are not substantially a single frequency.

FIG. 4 is a flow diagram illustrating a sequence of events 400 in the compensating of a corner frequency of a filter using out-of-band signals. Sequence of events 400 may be descriptive of operations taking place in a wireless receiver performing corner frequency compensation. The compensation of the corner frequency of a filter, such as an ABF, may be performed periodically. Alternatively, the computing of the corner frequency may occur when a specified event occurs. For example, the computing of the corner frequency may occur prior to receiving a transmission, when performance of the wireless transceiver reaches a threshold, when measured performance metrics reach a threshold, when a request to perform corner frequency compensation is received, a detected change in operating conditions, a detected change in supply voltage, and so forth.

The corner frequency compensation may begin with an injection of out-of-band signals (block 405). In general, the number of out-of-band signals injected may be dependent on the ABF's order. For an n-th order ABF used in a Cartesian wireless receiver, n pairs of out-of-band signals may be injected. Each pair of out-of-band signals comprises an out-of-band signal for an I-phase signal path and a Q-phase signal path. For example, a pair of out-of-band signals may include a cosine wave and a sine wave, with the cosine wave and the sine wave having the same frequency.

After injecting a pair of out-of-band signal at a frequency, measurements of the ABF's phase response at the frequency of the out-of-band signals may be made (block 410). Generally, if multiple pairs of out-of-band signals are to be used, a pair of out-of-band signals may be injected one at a time and the measurement of the ABF's phase response made before another pair is injected.

If multiple pairs of out-of-band signals are to be injected, the injecting (block 405) and the measuring (block 410) may be repeated for each pair of out-of-band signals. Once all of the pairs of out-of-band signals have been injected and the phase response of the ABF has been measured, then the corner frequency of the ABF may be computed using the measured phase response (block 415).

The computed corner frequency of the ABF may then be compared with a desired corner frequency of the ABF (block 420). If the computed corner frequency and the desired corner frequency are equal or differ by less than a threshold, then the corner frequency does not need compensation and may terminate. However, if the computed corner frequency and the desired corner frequency differ by more than the threshold, then corner frequency compensation is needed. The corner frequency compensation may be performed by adjusting capacitor, resistor, or inductor values in the ABF (block 425). The capacitor, resistor, or inductor values may be adjusted by switching in and/or out different capacitors/resistors/inductors in the ABF, digitally adjusting capacitor/resistor/inductor values based on a control word, and so forth.

Since in a Cartesian wireless receiver there are two signal paths (the I-phase and Q-phase signal paths), any adjustments should be made to both signal paths at substantially the same time. By making the adjustments to both signal paths at the same time, potential mismatches in the two signal paths may be minimized. Additionally, the injection of the out-of-band signals should also occur at substantially the same time, again to minimize potential mismatches in the two signal paths.

After adjusting the ABF (block 425), the corner frequency compensation may be repeated to determine if the adjustments are sufficient. The corner frequency compensation may be repeated until the computed corner frequency differs from the desired corner frequency by less than the threshold.

In addition to using the computed corner frequency to compare and then adjust the ABF, other relevant parameters of the transfer function of the ABF (such as Q and ωₙ) may also be used to compare with their desired values to guide and assist in the tuning of the ABF.

Although the embodiments and their advantages have been described in detail, it should be understood that various changes, substitutions and alterations can be made herein without departing from the spirit and scope of the invention as defined by the appended claims. Moreover, the scope of the present application is not intended to be limited to the particular embodiments of the process, machine, manufacture, composition of matter, means, methods and steps described in the specification. As one of ordinary skill in the art will readily appreciate from the disclosure of the present invention, processes, machines, manufacture, compositions of matter, means, methods, or steps, presently existing or later to be developed, that perform substantially the same function or achieve substantially the same result as the corresponding embodiments described herein may be utilized according to the present invention. Accordingly, the appended claims are intended to include within their scope such processes, machines, manufacture, compositions of matter, means, methods, or steps.

What is claimed is:

1 A method for computing a corner frequency of a filter, the method comprising:
injecting a signal into an input of the filter, wherein the signal has value substantially only at a frequency outside of a passband of the filter;
measuring a phase response of the filter at the frequency; and
computing a corner frequency of the filter using the phase response.

2. The method of claim 1, wherein the measuring a phase response comprises:
demodulating an output of the filter;
determining a direct current (DC) component of the demodulated output of the filter;
selecting a value of the DC component; and
determining the phase response from the value of the DC component.

3. The method of claim 2, wherein the filter is used in a wireless Cartesian receiver having two signal paths, wherein demodulating the output produces a first demodulated output and a second demodulated output, and wherein determining the phase response comprises determining a first phase response for a first signal path from the value of the DC component of the first demodulated output.

4. The method of claim 3, wherein determining the first phase response comprises evaluating
$${θ}_{I} = - {tan}^{- 1} ( \frac{{L}_{Q}}{{L}_{I}} ) ,$$
where L_{Q} is the value of the DC component of the first demodulated output, and L_{I} is the value of the DC component of the second demodulated output.

5. The method of claim 3, wherein the wireless Cartesian receiver comprises a second filter, the method further comprising:
injecting a second signal into an input of the second filter, wherein the second signal at a second frequency outside of a passband of the filter;
measuring a second phase response of the second filter at the second frequency; and
computing a corner frequency of the second filter using the second phase response.

6. The method of claim 5, wherein measuring the second phase response comprises:
demodulating an output of the second filter;
determining a second DC component of the demodulated output of the second filter;
selecting a value of the second DC component; and
determining the second phase response from the value of the second DC component.

7. The method of claim 6, wherein the demodulating an output of the second filter produces a third demodulated output and a fourth demodulated output, and wherein the determining the second phase response comprises evaluating
$${θ}_{Q} = {tan}^{- 1} ( \frac{{\tilde{L}}_{I}}{{\tilde{L}}_{Q}} ) ,$$
where \tilde{L}_{Q} is the value of the DC component of the third demodulated output, and \tilde{L}_{I} is the value of the DC component of the fourth demodulated output.

8. The method of claim 1, wherein computing the corner frequency comprises:
determining an expression of the phase response from a transfer function of the filter; and
computing the corner frequency using the expression.

9. The method of claim 8, wherein the filter is a first-order low-pass filter with transfer function
$$H ( s ) = \frac{{G}_{0}}{1 + j \frac{f}{{f}_{c}}} ,$$
wherein the expression of the phase response is
$$ϕ = - {tan}^{- 1} ( \frac{f}{{f}_{c}} ) ,$$
where f_{c} is the corner frequency, G₀ is the magnitude response of the filter at DC, and wherein the computing the corner frequency using the expression comprises evaluating
$${f}_{c} = - \frac{f}{tan ( {ϕ}_{1} )} ,$$
where φ₁ is the phase response of the filter at the frequency f.

10. The method of claim 8, wherein the filter is a second-order low pass filter with transfer function
$$H ( s ) = \frac{{G}_{0}}{{( \frac{s}{{ω}_{n}} )}^{2} + \frac{1}{Q} ( \frac{s}{{ω}_{n}} ) + 1} ,$$
wherein the expression of the phase response is
$$ϕ = - {tan}^{- 1} ( \frac{\frac{1}{Q} ( \frac{ω}{{ω}_{n}} )}{1 - {( \frac{ω}{{ω}_{n}} )}^{2}} ) ,$$
where Q is the quality of the filter, ω=2πf and f is the frequency, and ωₙ is the natural frequency, and the method further comprising:
sequentially injecting two signals into the input of the filter, the two signals at different frequencies outside of the passband of the filter; and
measuring a phase response of the filter at each of the two frequencies.

11. The method of claim 10, wherein computing the corner frequency using the expression comprises:
solving for Q and ωₙ using the expression and the phase response at the two frequencies; and
evaluating
$${f}_{c} = \frac{\sqrt{x} {ω}_{n}}{2 π} , where x = \frac{( 2 - \frac{1}{{Q}^{2}} ) + \sqrt{{( 2 - \frac{1}{{Q}^{2}} )}^{2} + 4}}{2} .$$

12. A method for adjusting a corner frequency of a filter, the method comprising:
computing the corner frequency of the filter, wherein the computing uses a measured phase response of the filter at a frequency outside of a passband of the filter;
determining if the computed corner frequency is different from a desired corner frequency by more or less than a threshold;
if the computed corner frequency differs from the desired corner frequency by more than the threshold,
adjusting parameters of the filter to alter the corner frequency, and
repeating the computing and the determining; and
if the computed corner frequency differs from the desired corner frequency by less than the threshold, leaving the parameters of the filter unchanged.

13. The method of claim 12, wherein the computing comprises:
injecting a signal into an input of the filter, wherein the signal has value substantially only at the frequency;
measuring a phase response of the filter at the frequency; and
computing the corner frequency of the filter using the phase response.

14. The method of claim 13, wherein the filter is an n-th order filter, and wherein the computing further comprising repeating the injecting and the measuring for n-1 other signals, wherein each of the n signals has value substantially only at one of n different frequencies, each frequency outside of the passband of the filter.

15. The method of claim 14, wherein the computing comprises computing the corner frequency of the filter using the phase response at each of the n frequencies.

16. The method of claim 13, further comprising prior to the injecting:
adjusting parameters of the filter to maximize a corner frequency of the filter;
injecting a second signal into the input of the filter, wherein the second signal has value substantially only at a second frequency outside of the passband of the filter;
measuring a second phase response of the filter at the second frequency; and
returning the parameters of the filter to their state prior to the adjusting.

17. The method of claim 16, further comprising prior to computing the corner frequency of the filter using the phase response, subtracting the second phase response from the phase response.

18. The method of claim 12, wherein the adjusting comprises changing the parameters to move the corner frequency closer to the desired corner frequency.

19. The method of claim 18, wherein the changing comprises changing a capacitance value, a resistance value, and/or an inductance value of the filter.

20. A receiver comprising:
a signal path coupled to a signal input and to a baseband unit, the signal path comprising,
a mixer configured to demodulate a signal provided by the signal input, to change the signal to a baseband signal,
a filter coupled to the mixer, the filter configured to attenuate undesired signals outside of a frequency band of interest,
an analog to digital converter, the analog to digital converter configured to digitize the filtered baseband signal, and
a decimation filter coupled to the analog to digital converter, the decimation filter configured to reduce a number of samples produced by the analog to digital converter;
a signal generator coupled to the filter, the signal generator configured to generate an out-of-band signal having substantially value only at a frequency outside of a passband of the filter;
a demodulator coupled to the decimation filter and to the signal generator, the demodulator configured to demodulate the reduced digital sample stream produced by the decimation filter with the out-of-band signal;
a value estimator coupled to the demodulator, the value estimator configured to extract a direct current (DC) component from the demodulated digital sample stream and to select a value of the DC component; and
a processor coupled to the value estimator, the processor configured to compute a phase response of the filter from the value provided by the value estimator.

21. The receiver of claim 20, wherein the receiver is a Cartesian receiver having a second signal path, the receiver further comprising a second signal generator coupled to the second signal path, the second signal generator configured to generate a second out-of-band signal having substantially values only at the frequency outside of a passband of a second filter in the second signal path.

22. The receiver of claim 21, further comprising:
a second demodulator coupled to a second decimation filter in the second signal path and to the signal generator, the second demodulator configured to demodulate a second reduced digital sample stream produced by the second decimation filter with the second out-of-band signal; and
a second value estimator coupled to the second demodulator, the second value estimator configured to extract a second DC component from a second demodulated digital sample stream and to select a second value of the second DC component.
